(19) United States
(12) Patent Application Publication
(10) Pub. No.: US 2025/0350304 A1
(43) Pub. Date: Nov. 13, 2025

(54) RADIO FREQUENCY FRONT-END CIRCUIT WITH EXTENDED DYNAMIC RANGE

(71) Applicant: QUALCOMM Incorporated, San Diego, CA (US)

(72) Inventors: Arild KOLSRUD, El Cajon, CA (US); Mahbod MOFIDI, San Diego, CA (US)

(21) Appl. No.: 18/658,667

(22) Filed: May 8, 2024

(51) Int. Cl. H04B 1/00; H03F 3/19

(52) U.S. Cl. CPC H04B 1/006; H03F 3/19; H03F 2200/294; H03F 2200/451

(57) ABSTRACT

Techniques and apparatus for routing signals with a radio frequency (RF) front-end circuit are provided. One example RF front-end circuit generally includes a first RF module, a second RF module, and a switching circuit for selecting a first signal path from an antenna to an output of the first RF module when power of a signal received at the antenna is at or below a first threshold value, or a second signal path from the antenna to the output of the first RF module when power of the signal received at the antenna is at or above a second threshold value.

### TECHNICAL FIELD

Certain aspects of the present disclosure generally relate to electronic circuits and, more particularly, to techniques and apparatus for using multiple independent chips.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, 5G New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include a transmission digital-to-analog converter (TX DAC), which may be used, for example, to convert a digital signal to an analog signal for signal processing (e.g., filtering, upconverting, and amplifying) before transmission by one or more antennas.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure provide a radio frequency (RF) front-end circuit. The RF front-end circuit generally includes a first RF module, a second RF module, and a switching circuit for selecting (i) a first signal path from an antenna to an output of the first RF module when power of a signal received at the antenna is at or below a first threshold value, or (ii) a second signal path from the antenna to the output of the first RF module when power of the signal received at the antenna is at or above a second threshold value.

Certain aspects of the present disclosure are directed to a method for routing signals. The method generally includes receiving a signal at an antenna and selecting, based on a power of the signal, a first signal path from the antenna to an output of a first radio frequency (RF) module or a second signal path from the antenna to the output of the first RF module.

Certain aspects of the present disclosure provide a system for routing signals. The system generally includes a first signal path from an antenna to an output of a first RF module, a second signal path from the antenna to the output of the first RF module, a switching circuit, memory having computer-executable instructions stored thereon, and one or more processors coupled to the memory. The one or more processors are generally, individually or collectively, configured to (i) select, using the switching circuit, the first signal path when power of a signal received at the antenna is at or below a first threshold value, or (ii) select, using the switching circuit, the second signal path when power of the signal received at the antenna is at or above a second threshold value.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example a base station (BS) and user equipment (UE), in which aspects of the present disclosure may be practiced.

FIGS. 3A and 3B illustrate an example radio frequency (RF) front-end circuit, in which aspects of the present disclosure may be practiced.

FIG. 4 is an example plot of the dynamic range of the example RF front-end circuit of FIGS. 3A and 3B, in accordance with certain aspects of the present disclosure.

FIGS. 5A, 5B, 5C, and 5D illustrate an example RF front-end circuit with a switching circuit implemented as a time division multiple access (TDMA) switch, in which aspects of the present disclosure may be practiced.

FIGS. 6A, 6B, 6C, 6D, and 6E illustrate an example RF front-end circuit with a switching circuit implemented as a switch with three output paths, in which aspects of the present disclosure may be practiced.

FIGS. 7A, 7B, and 7C illustrate an example RF front-end circuit with a switching circuit implemented as a directional coupler, in which aspects of the present disclosure may be practiced.

FIGS. 8A, 8B, 8C, and 8D illustrate an example RF front-end circuit with a switching circuit implemented in the front-end module of the RF front-end circuit, in which aspects of the present disclosure may be practiced.

FIGS. 9 and 10 are flow diagrams of example operations for operating an RF front-end circuit, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Often, it is preferable that radio frequency (RF) front-end circuits include multiple independent chips (e.g., integrated circuits) to enable support for multiple radio access technologies (RATs). For example, an RF front-end circuit may include both a Bluetooth (BT) chip and a wireless local-area network (WLAN) chip. In such cases, the multiple independent chips may share a single antenna to save on costs, particular in cost-sensitive devices such as Internet of Things (IoT) devices.

Unfortunately, the dynamic range of an RF front-end circuit with multiple independent chips that share single antenna may be limited as a result of individual signal paths from the antenna to the multiple independent chips.

Certain aspects of the present disclosure are directed to an RF front-end circuit that includes a switching circuit configured to select between multiple signal paths, depending on a power level of a signal received at an antenna coupled to the RF front-end circuit. Such a switching circuit may form multiple signal paths between the antenna and the multiple independent chips, each chip enabling a different radio access technology (RAT).

For example, in an RF front-end circuit that supports both BT and WLAN, low-power BT signals may be routed through the WLAN receiver, which typically has larger gain (than the BT receiver), allowing the low-power BT signal to be amplified before being returned to the BT signal path. Higher power BT signals may be routed to the BT path through via a directional coupler (or other such circuit). Since the BT signal is much stronger in this case, the BT receiver may be able to meet linearity requirements without concern for the noise figure. Due to attenuation through the coupler (e.g., 10 dB), the solution proposed herein may increase the RF front-end dynamic range (e.g., by at least 10 dB), making the BT receiver less prone to saturation.

In this manner, aspects of the present disclosure may expand the dynamic range of the RF front-end circuit without adding extensive additional circuitry and with minimal cost. In addition, certain embodiments of the switching circuit proposed herein may enable the multiple independent chips of the RF front-end circuit to both receive signals from the antenna concurrently.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

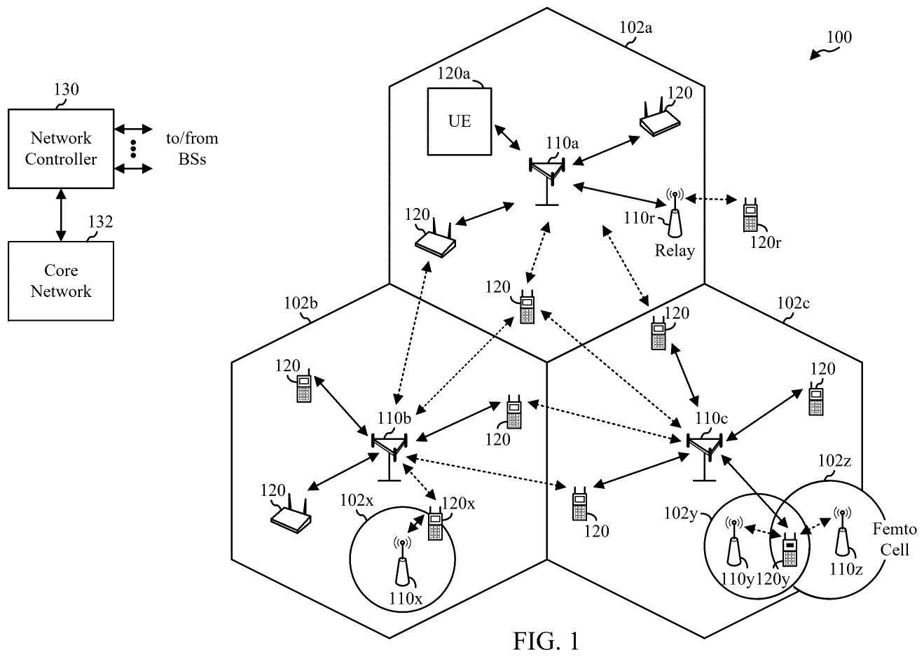

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS 110. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nap of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a digital-to-analog converter (DAC) with an adaptive calibration scheme, as described in more detail herein.

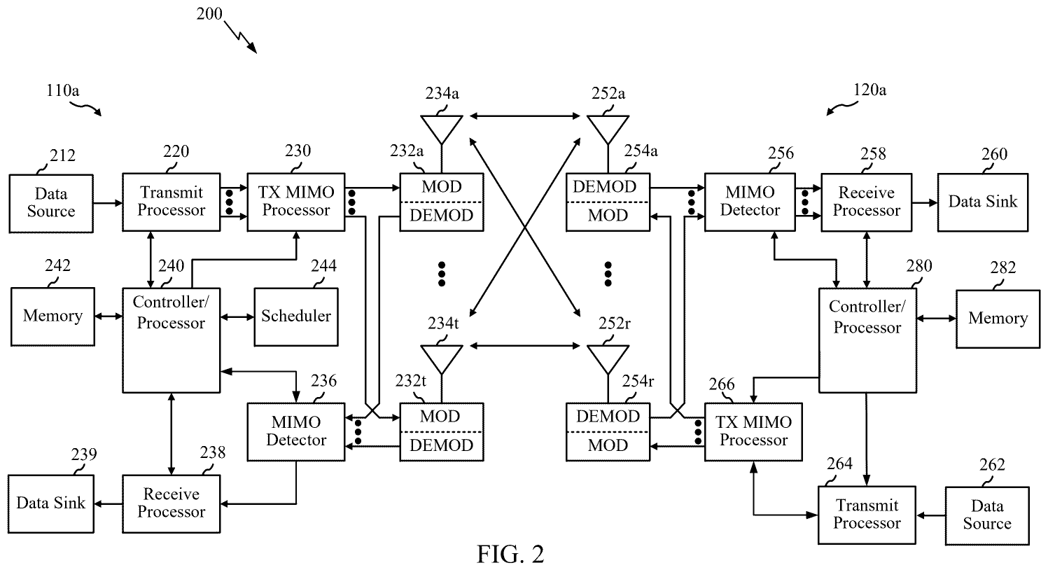

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232 and/or the transceivers 254 may include a digital-to-analog converter (DAC) with adaptive calibration circuitry, as described in more detail herein. NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Front-End Circuit

Certain aspects of the present disclosure are directed to an RF front-end circuit that includes a switching circuit configured to select between multiple signal paths, routing received RF signals to a first radio or second radio, depending on a power level of the RF signals.

For example, low-power BT signals may be routed through a WLAN receiver allowing the low-power BT signal to be amplified before being returned to the BT signal path. Higher power BT signals may be routed to the BT path. Since the BT signal is much stronger in this case, the BT receiver may be able to meet linearity requirements without concern for the noise figure. Due to attenuation through the switching circuit (e.g., through a 10 dB coupler or attenuator making the BT receiver less prone to saturation), the solution proposed herein may increase the RF front-end.

It should be noted that BT and WLAN are just example RATs and the techniques proposed herein may be used to increase dynamic range of RF front-end circuits with various other types of RAT modules in different implementations.

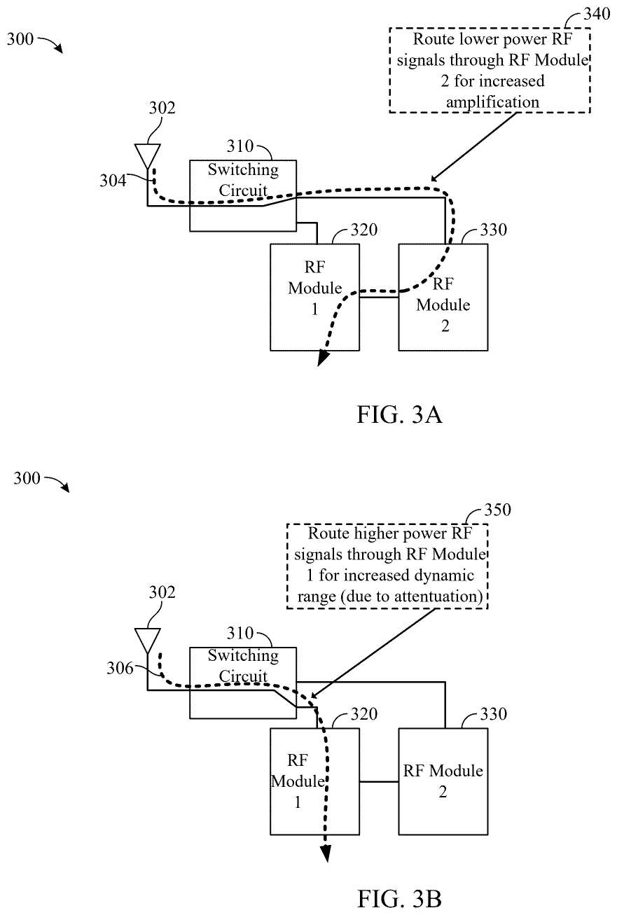

FIG. 3A illustrates an example of an RF front-end circuit 300 in accordance with certain aspects of the present disclosure. The RF front-end circuit 300 may help increase dynamic range for the first RAT (RAT 1) by routing low power RF signals through the second RF module 330 (that has a higher gain than the first RF module 320), as shown in FIG. 3A, or routing higher power RF signals through the first RF module 330 after attenuation (e.g., by 10 dB) through the switching circuit, as shown in FIG. 3B.

As illustrated, the RF front-end circuit 300 may include an antenna 302, a switching circuit 310, a first RF module 320 (labeled “RF Module 1”), and a second RF module 330 (labeled “RF Module 2”). Each of the first RF module 320 and the second RF module 330 may be implemented by an integrated circuit (e.g., a front-end integrated circuit). In some cases, the first RF module 320 may include or be implemented as a Bluetooth (BT) RF module, and the second RF module 330 may include or be implemented as a wireless local area network (WLAN) RF module.

RF signals received via the antenna 302 may be routed to the first RF module 320 or the second RF module 330, via the switching circuit 310.

RF signals received via the antenna 302 may be associated with the technology of the first RF module 320 (e.g., BT signals in the 2 GHz spectrum band) or the second RF module 330 (e.g., WLAN signals in the 5 GHz spectrum band). WLAN signals may be routed through the switch circuit 310 to the second RF module 320, and BT signals may be routed to the first RF module 320 directly (via switching circuit 310) or through the second RF module 330 to the first RF module 320.

The switching circuit 310 may be configured to select a first signal path 304 to route an RF signal from antenna 302 to the first RF module 320, as illustrated in FIG. 3A, or to select a second signal path 306 to route the RF signal to the second RF module 330, as illustrated in FIG. 3B. As will be described in greater detail below, in some cases, which switching circuit the RF signal is routed to may depend on a power of the RF signal received at the antenna 302.

In certain aspects, the switching circuit 310 may be controlled by an automatic gain control (not illustrated), and the automatic gain control may be configured to select between the first signal path 304 and the second signal path 306 based on the power of the received RF signal.

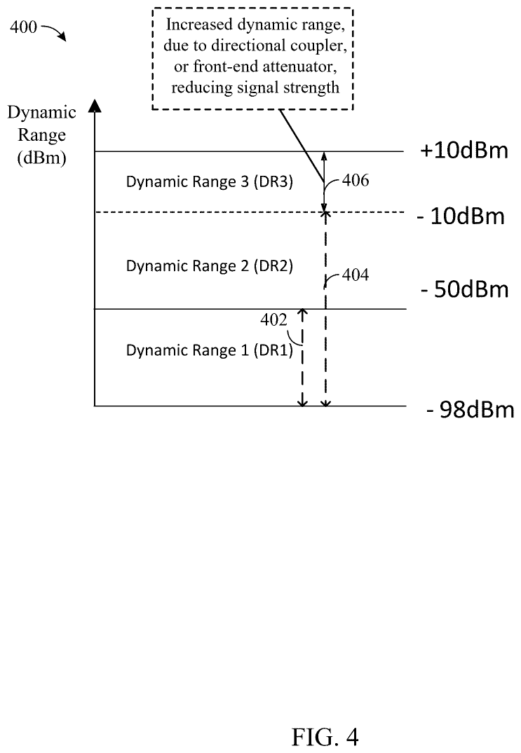

As noted at 340 in FIG. 3A, routing lower power RF signals (e.g., BT signals) to the second RF module 330 may take advantage of higher gain amplifiers in the second RF module 330. As noted at 350 in FIG. 3B, routing higher power RF signals (e.g., BT signals) to the first RF module 320 may increase dynamic range due to attenuation inherent in the switching circuit 310 (e.g., resulting in the 10 dB increase in dynamic range shown in FIG. 4).

The dynamic range of a circuit generally refers to the ratio of the highest signal level the circuit can handle (e.g., in dB relative to 1 mW of power-dBm), to the lowest signal level the circuit can handle (in dBm). Plot 400 of FIG. 4 illustrates examples of dynamic ranges that may be achievable using RF front-end circuits in accordance with aspects of the present disclosure.

The example plot 400 shows how a reduction in signal strength due to attenuation in the switching circuit (e.g., via a directional coupler or front-end attenuator) and/or extra gain by routing an RF signal of one RAT through an RF module of another RAT may result in an increase in dynamic range (e.g., by 10 dB) of the RF front-end circuit (e.g., when receiving BT signals), as indicated at 406. In the illustrated example, without the attenuation, the RF front-end circuit may be able achieve a dynamic range 404, by utilizing both first RF module 320 and second RF module 330 or dynamic range 402 if using just one RF module.

The switching circuit 310 may be implemented as, for example, a switch, a directional coupler, or front-end attenuator, and may be configured to attenuate the power of the RF signal received at the antenna 302 before the RF signal reaches the first RF module 320 or the second RF module 330. In this manner, the RF signal received at the antenna 302 may be attenuated, enabling the dynamic range of the RF front-end circuit 300 to be expanded as indicated at 406. In some cases, the attenuation of the switching circuit 310 may be configurable (e.g., based on a particular application) and, in such cases, the increase of the dynamic range may be similarly configurable. For example, if the switching circuit 310 is implemented as a 10 dB directional coupler, then the dynamic range may be increased by 10 dB.

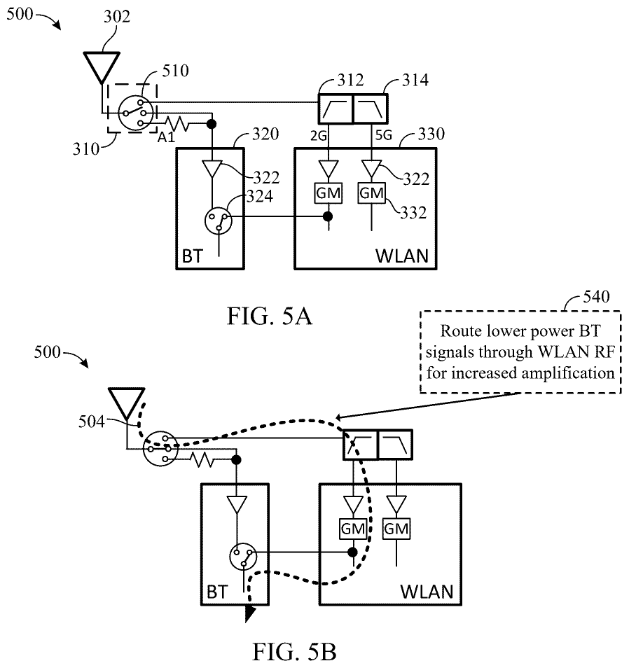

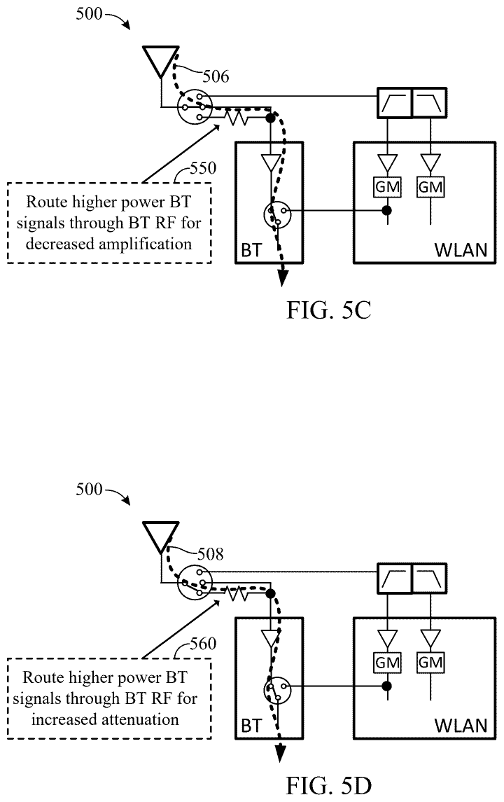

FIGS. 5-9 illustrate various example configurations of RF front-end circuits in accordance with aspects of the present disclosure. Each example configuration may achieve a boost in dynamic range, but each example configuration may implement the switching circuit in a different manner.

For example, FIGS. 5A-D illustrate an example RF front-end circuit 500 with a switching circuit 310 implemented as a time division multiple access (TDMA) switch 510 and a switch 324, in which aspects of the present disclosure may be practiced.

As illustrated in FIG. 5A, the RF front-end circuit 500 may be similar to the RF front-end circuit 300, but may further include a high pass filter 312 and a low pass filter 314, as illustrated. The high pass filter may be utilized for RF signals for the second RF module 330 (e.g., WLAN signals in the 5 GHz spectrum band), and the low pass filter may be utilized for RF signals for the first RF module 320 (BT signals in the 2 GHz spectrum band).

As illustrated, the first RF module 320 may include an internal low noise amplifier (LNA) 322 and switch 324 (which could be considered part of the switching circuit 310). The second RF module 320 may include multiple LNAs 322 and multiple transconductance (gm) stages 332. The second RF module 320 may also include a matching network (not illustrated) to enable the proper routing (e.g., via tapping or splitting) of the received RF signal through the second RF module 330 to the first RF module 320. The switch 510 may be configured to select between the signal path 504 (illustrated in FIG. 5B), the signal path 506 (illustrated in FIG. 5C), and the signal path 508 (illustrated in FIG. 5D) based on the power of the RF signal received at the antenna 302.

The dynamic range of the RF front-end circuit 500 may be increased by routing low power RF signals (e.g., BT signals) through a path through the second RF module 330 to the first RF module 320 (as shown in FIG. 5B), or routing higher power RF signals (e.g., BT signals) to the first RF module 320 through a path without an attenuating element A1 (as shown in FIG. 5C) or through a path with an attenuating element A1 (as shown in FIG. 5D).

As illustrated in FIG. 5B, when the signal path 504 is selected, the RF signal received at the antenna 302 may be routed through the switching circuit 310 to the second RF module 330. The RF signal may then be routed through the LNA 322 (e.g., to boost the RF signal) and through the switch 324 to the output of the first RF module 320, as illustrated. The signal path 504 may be selected by the switching circuit 310 when the power of the RF signal is lower (as noted at 540 in FIG. 5B) to take advantage of higher gain amplifiers in the second RF module 330.

As illustrated in FIG. 5C, when the signal path 506 is selected, the (higher power) RF signal received at the antenna 302 may be routed through the switch 510 to the first RF module 320. The RF signal may then be routed through the LNA 322 (e.g., to boost the RF signal) and through the switch 324 to the output of the first RF module 320, as illustrated. The signal path 506 may be selected when the power of the RF signal is higher (as noted at 550 in FIG. 5C) but when additional attenuation by the attenuating element A1 is undesirable (e.g., due to over-attenuation of the received RF signal).

As illustrated in FIG. 5D, when the signal path 508 is selected, the RF signal received at the antenna 302 may be routed through the switch 510 and an attenuating element A1 (e.g., configured to attenuate the RF signal) to the first RF module 320. The RF signal may then be routed through the LNA 322 (e.g., to boost the RF signal) and through the switch 324 to the output of the first RF module 320, as illustrated. In this manner, the dynamic range of the RF front-end circuit 500 may be increased due to the attenuation inherent in the switch 510 and the attenuating element A1 (e.g., resulting in an increased dynamic range as indicated at 406 of FIG. 4).

The signal path 506 may be selected when the power of the RF signal is higher (as noted at 560 in FIG. 5D) to take advantage of the increased attenuation. In certain aspects, the attenuating element A1 may be configurable and may attenuate the RF signal such that the RF signal is not overly large for the LNA 322 included in the first RF module 320. In some cases, the attenuating element A1 may be implemented by a resistive element, or any other element configured to attenuate an RF signal.

When the switching circuit 310 is implemented by the switch 510 (as in FIGS. 5A-D), the first RF module 320 and the second RF module 330 may be unable to both receive RF signals from different RAT technologies (e.g., a BT signal and a WLAN signal) from the antenna 302 simultaneously. That is, the RF front-end circuit 500 may switch between routing the received RF signal to the first RF module 320 (e.g., for the BT RAT technology) and the second RF module 330 (e.g., for the WLAN RAT technology) using the switch 510.

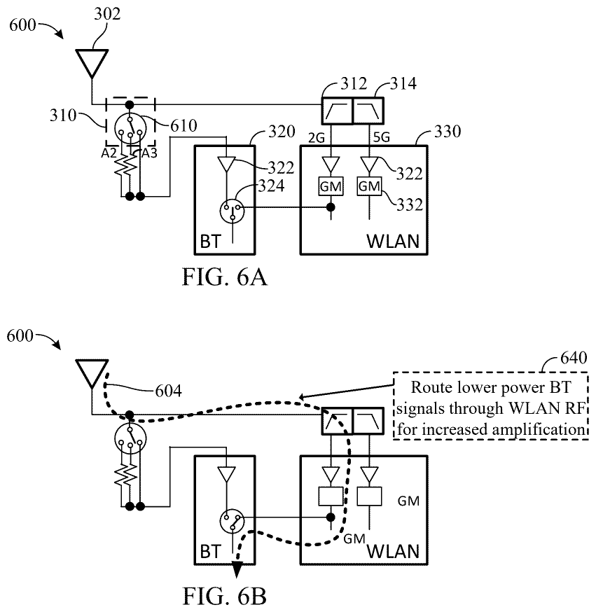

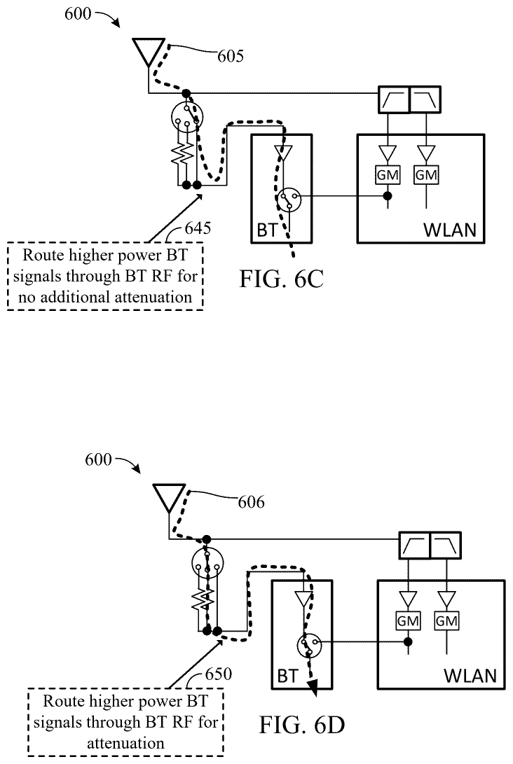

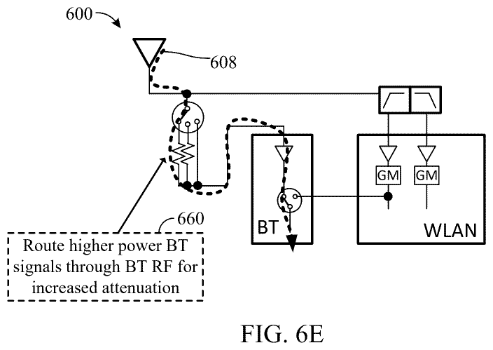

The RF front-end circuits 600, 700, 800 described below with reference to FIGS. 6-8, however, may be capable of receiving RF signals for the first RF module 320 and the second RF module 330 concurrently. This may be achieved, for example, by including one or more signal paths which bypass the second RF module 330 and pass straight to the first RF module 320, each signal path being configured to handle RF signals different based on the power of the RF signal. That is, RF signals for the second RF module 330 (e.g., WLAN signals in the 5 GHz spectrum band) may be routed through the switching circuit 310 to the second RF module 330 while RF signals for the first RF module 320 (BT signals in the 2 GHz spectrum band) are routed through the switching circuit 310 and through one or more configurable signal paths to the first RF module 320.

FIGS. 6A-E illustrate an example RF front-end circuit 600 with a switching circuit 310 implemented as a switch 610 with three output paths, in which aspects of the present disclosure may be practiced.

As illustrated in FIG. 6A, the RF front-end circuit 600 may be similar to the RF front-end circuit 500, but the switching circuit 310 (implemented as the switch 610 and the switch 324) may include three paths, one without an attenuating element, one with attenuating element A2 (which may be similar to attenuating element A1 described above), and a third with attenuating element A3 (which may also be similar to attenuating element A1 described above). In some cases, the attenuating element A2 and/or the attenuating element A3 may each be implemented with a resistive element.

The dynamic range of the RF front-end circuit 600 may be increased by routing low power RF signals (e.g., BT signals) through a path without an attenuating element through the second RF module 320, as shown in FIG. 6B and routing higher power RF signals (e.g., BT signals) to the first RF module 330 through the switching circuit 310 and attenuating element A2 (as shown in FIG. 6D) or attenuating element A3 (as shown in FIG. 6E). In certain aspects, one of the attenuating elements A2 and A3 may have a relatively lower attenuation than the other. The higher power RF signals may be split among high power RF signals and medium power RF signals (e.g., the medium power RF signals still being higher power signals than the lower power signals routed through the second RF module 320).

When the RF front-end circuit 600 is receiving RF signals for the second RF module 330 (e.g., WLAN signals), and the signal path 604 may be unavailable for use for receiving BT signals, and the RF front-end circuit may be configured to route low power RF signals (e.g., BT signals) through the switch 610, the LNA 322, and the switch 324 to the output of the first RF module 320, effectively bypassing the second RF module 330. In this manner, the RF front-end circuit 600 may be capable of receiving RF signals for the first RF module 320 and the second RF module 330 concurrently.

The switching circuit 310 may be configured to select the signal path with either attenuating element A2 or A3 based on the power of the RF signal received at the antenna 302. For example, when the power of the RF signal received at the antenna is high, the switching circuit 310 may select the signal path with the higher attenuating element (e.g., the signal path 608 in FIG. 6E), and when the power of the RF signal received at the antenna 302 is medium, the switching circuit 310 may select the signal path with the lower attenuating element (e.g., the signal path 606 in FIG. 6D).

As illustrated in FIG. 6B, when the signal path 604 is selected, the RF signal received at the antenna 302 may be routed through the switch 610 to the second RF module 330. The RF signal may then be routed through the LNA 322 (e.g., to boost the RF signal) and through the switch 324 to the output of the first RF module 320, as illustrated. The signal path 604 may be selected by the switching circuit 310 when the power of the RF signal is lower (as noted at 640 in FIG. 6B) to take advantage of higher gain amplifiers in the second RF module 330.

As illustrated in FIG. 6C, when the signal path 605 is selected, the RF signal received at the antenna 302 may be routed through the switch 610 to the first RF module 320 (bypassing attenuating elements A2 and A3). The RF signal may then be routed through the LNA 322 (e.g., to boost the RF signal) and through the switch 324 to the output of the first RF module 320, as illustrated. The signal path 605 of FIG. 6C may be selected when the power of the RF signal is higher (as noted at 645 in FIG. 6C) but insufficiently high enough to take advantage of the additional attenuation at attenuating element A2 or attenuating element A3. For example, the signal path 605 of FIG. 6C may be selected when the power of the RF signal is higher but attenuating element A2 and attenuating element A3 would excessively attenuate the RF signal, and thus using signal path 605 may avoid additional attenuation and results in a preferred RF signal at the output of the first RF module 320.

As illustrated in FIG. 6D, when the signal path 606 is selected, the RF signal received at the antenna 302 may be routed through the switch 610 and an attenuating element A3 (e.g., configured to attenuate the RF signal) to the first RF module 320. The RF signal may then be routed through the LNA 322 (e.g., to boost the RF signal) and through the switch 324 to the output of the first RF module 320, as illustrated. In this manner, the dynamic range of the RF front-end circuit 600 may be increased due to the attenuation inherent in the switch 610 and the attenuating element A3. The signal path 606 of FIG. 6D may be selected when the power of the RF signal is higher (as noted at 660 in FIG. 6D) to take advantage of the increased attenuation. For example, the signal path 606 of FIG. 6D may be selected when the power of the RF signal is higher but the attenuating element A2 would excessively attenuate the RF signal, and thus passing through attenuating element A3 results in a preferred RF signal at the output of the first RF module 320.

As illustrated in FIG. 6E, when the signal path 608 is selected, the RF signal received at the antenna 302 may be routed through the switch 610 and an attenuating element A2 (e.g., configured to attenuate the RF signal) to the first RF module 320. The RF signal may then be routed through the LNA 322 (e.g., to boost the RF signal) and through the switch 324 to the output of the first RF module 320, as illustrated. In this manner, the dynamic range of the RF front-end circuit 500 may be increased due to the attenuation inherent in the switch 610 and the attenuating element A2. The signal path 608 may be selected when the power of the RF signal is higher (as noted at 660 in FIG. 6E) to take advantage of the higher attenuation (compared to signal path 606). In certain aspects, attenuating elements A2 and A3 may be configured to attenuate the RF signal such that the RF signal is not overly large for the LNA 322 included in the first RF module 320.

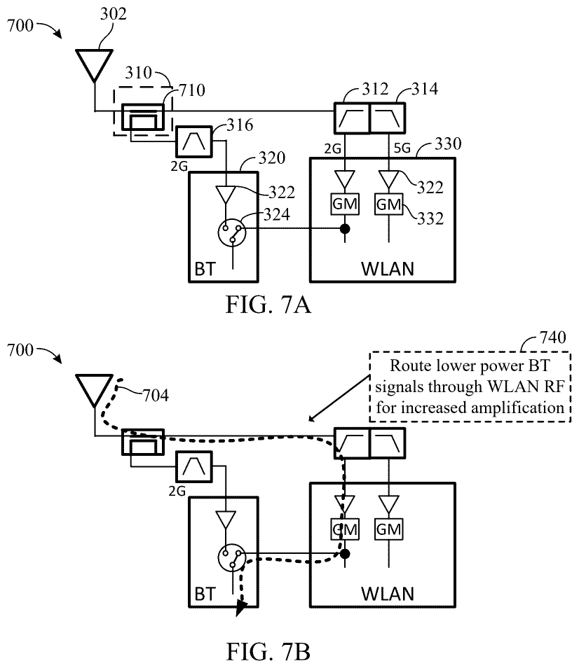

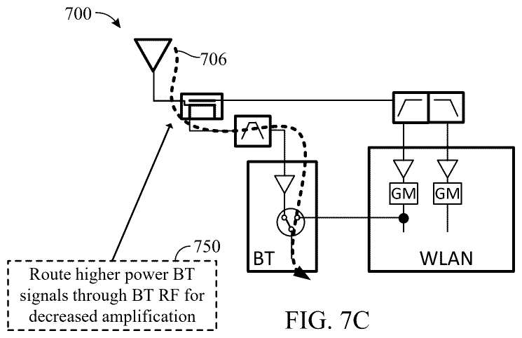

FIGS. 7A-C illustrate an example RF front-end circuit 700 with a switching circuit 310 implemented as a directional coupler 710, in which aspects of the present disclosure may be practiced. The RF front-end circuit 700 may be similar to the RF front-end circuit 700, but the switching circuit 310 may be implemented as the directional coupler 710 and the switch 324, the RF front-end circuit 700 may include a band-pass filter 316, and the RF front-end circuit 700 may not include attenuating elements, as illustrated. The attenuation of the directional coupler 710 may be configurable. For example, the directional coupler 710 may be, for example, a 10 dB directional coupler or a 20 dB directional coupler.

The dynamic range of the RF front-end circuit 700 may be increased by routing low power RF signals (e.g., BT signals) to the second RF module 320 (as shown in FIG. 7B), and routing higher power RF signals (e.g., BT signals) through the directional coupler 710 to the first RF module 330 (as shown in FIG. 7C). The use of the directional coupler 710 as illustrated may enable the RF front-end circuit 700 to receive RF signals for the first RF module 320 and the second RF module 330 concurrently.

As illustrated in FIG. 7B, when the signal path 704 is selected, the RF signal received at the antenna 302 may be routed through the directional coupler 710 to the second RF module 330. The RF signal may then be routed through the LNA 322 (e.g., to boost the RF signal) and through the switch 324 to the output of the first RF module 320, as illustrated. The signal path 704 may be selected by the directional coupler 710 when the power of the RF signal is lower (as noted at 740 in FIG. 7B) to take advantage of higher gain amplifiers in the second RF module 330.

As illustrated in FIG. 7C, when the signal path 706 is selected, the RF signal received at the antenna 302 may be routed through the directional coupler 710 and the band-pass filter 316 to the first RF module 320. The RF signal may then be routed through the LNA 322 (e.g., to boost the RF signal) and through the switch 324 to the output of the first RF module 320, as illustrated. In this manner, the dynamic range of the RF front-end circuit 700 may be increased due to the attenuation inherent in the directional coupler 710. The signal path 706 may be selected when the power of the RF signal is higher (as noted at 750 in FIG. 7C) to take advantage of the increased attenuation.

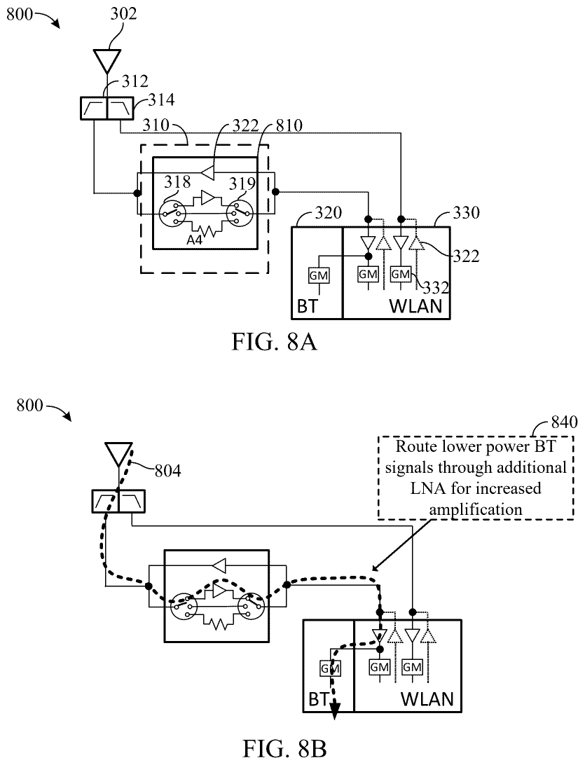

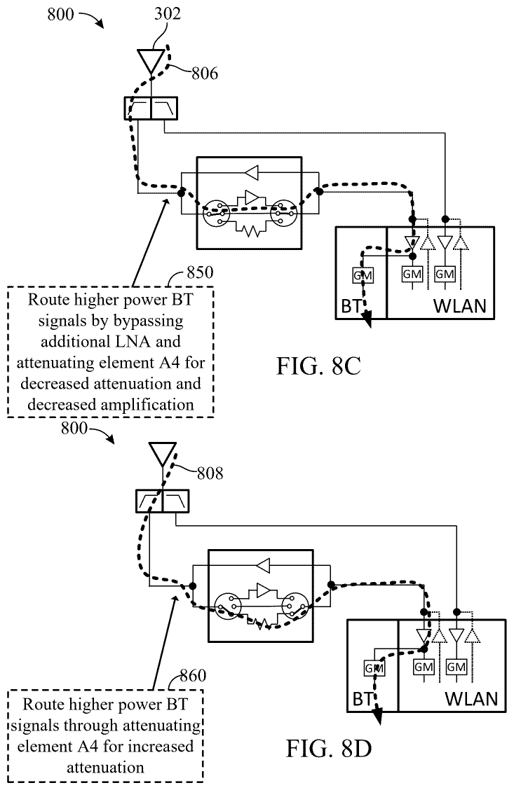

FIGS. 8A-D illustrate an example RF front-end circuit 800 with a switching circuit 310 implemented in a front-end module 810 of the RF front-end circuit 800, in which aspects of the present disclosure may be practiced. The RF front-end circuit 800 may be similar to the RF front-end circuit 500, but the switching circuit 310 (implemented in the front-end module 810) may include a switch 318, a switch 319, an attenuating element A4 (which may be similar to attenuating element A1 described above), and multiple LNAs 322. It is also noted that the RF front-end circuit 800 does not include switch 324.

The dynamic range of the RF front-end circuit 800 may be increased by routing low power RF signals (e.g., BT signals) through a path with the LNA 322 to the second RF module 330, as shown in FIG. 8B, and routing higher power RF signals (e.g., BT signals) through the front-end module 810 along a path without an attenuating element (as shown in FIG. 8C) or along a path with the attenuating element A4 (as shown in FIG. 8D). The higher power RF signals may be split among high power RF signals (e.g., path 808) and medium power RF signals (e.g., path 806, the medium power RF signals being higher power signals than the lower power signals). The use of the front-end module 810 as illustrated may enable the RF front-end circuit 800 to receive RF signals for the first RF module 320 and the second RF module 330 concurrently.

The switching circuit 310 may be configured to select the signal path with either attenuating element A4 or without an attenuating element based on the power of the RF signal received at the antenna 302. For example, when the power of the RF signal received at the antenna 302 is high, the switching circuit 310 may select (e.g., using the switches 318 and 319) the signal path with the attenuating element A4 (e.g., the signal path 808 in FIG. 8D), and the when the power of the RF signal received at the antenna 302 is medium, the switching circuit 310 may select (e.g., using the switches 318 and 319) the signal path with without the attenuating element (e.g., the signal path 806 in FIG. 8C).

As illustrated in FIG. 8B, when the signal path 804 is selected, the RF signal received at the antenna 302 may be routed through the switch 318, the LNA 322 (e.g., to boost the RF signal), and the switch 319 to the second RF module 330. The RF signal may then be routed through another LNA 322 (e.g., to again boost the RF signal) and the gm stage 332 to the output of the first RF module 320, as illustrated. The signal path 804 may be selected by the switching circuit 310 when the power of the RF signal is lower (as noted at 840 in FIG. 8B) to utilize of the LNA 322 in the front-end module 810.

As illustrated in FIG. 8C, when the signal path 806 is selected, the RF signal received at the antenna 302 may be routed through the switch 318 and the switch 319 to the second RF module 330. The RF signal may then be routed through the LNA 322 (e.g., to boost the RF signal) and through the gm stage 332 to the output of the first RF module 320, as illustrated. In this manner, the dynamic range of the RF front-end circuit 800 may be increased due to the attenuation inherent in the attenuating element A3. The signal path 806 may be selected when the power of the RF signal is higher (as noted at 850 in FIG. 8C) but when attenuation by the attenuating element A4 is undesirable (e.g., due to over-attenuation of the received RF signal).

As illustrated in FIG. 8D, when the signal path 808 is selected, the RF signal received at the antenna 302 may be routed through the switch 318, the attenuating element A4 (e.g., configured to attenuate the RF signal), the switch 319, and to the second RF module 330. The RF signal may then be routed through the LNA 322 (e.g., to boost the RF signal) and through the gm stage 332 to the output of the second RF module 330, as illustrated. In this manner, the dynamic range of the RF front-end circuit 800 may be increased due to the additional attenuation inherent in the attenuating element A4 (relative to the lower attenuation inherent in A3). The signal path 808 may be selected when the power of the RF signal is higher (as noted at 860 in FIG. 8D) to take advantage of the higher attenuation (compared to signal path 806). In certain aspects, the attenuating element A4 may be configured to attenuate the RF signal such that the RF signal is not overly large for the LNA 322 included in the first RF module 320.

### Example Operations for an RF Front-End Circuit

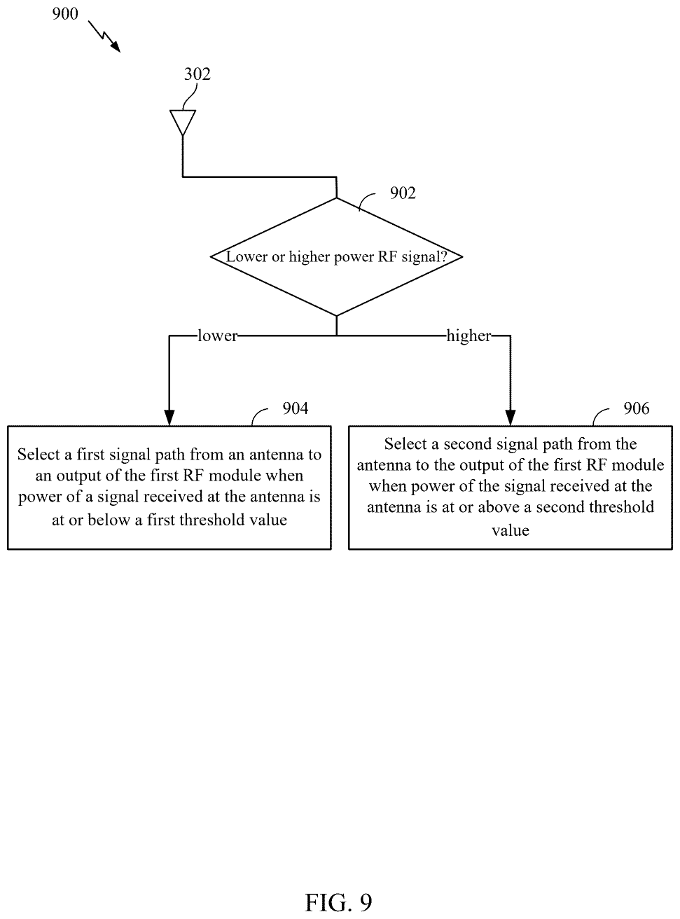

FIG. 9 is a flow diagram of example operations 900 for an RF front-end circuit (e.g., the RF front-end circuit 300, 500, 600, 700, and 800 of FIGS. 5A, 5B, 5C, 6A, 6B, 6C, 6D, 6E, 7A, 7B, 7C, 7D, 8A, 8B, 8C, and 8D, respectively), in accordance with certain aspects of the present disclosure.

The operations 900 may include, at block 902, determining whether the power of an RF signal received at an antenna (e.g., antenna 302) is higher or lower. When a power of a signal received at the antenna is at or below a first threshold value (e.g., the power is lower), a switching circuit (e.g., switching circuit 310) may select, at block 904, a first signal path from the antenna to an output of the first RF module (e.g., first RF module 320). When a power of a signal received at the antenna is at or above a second threshold value (e.g., the power is higher), the switching circuit may select, at block 906, a second signal path from the antenna to the output of the first RF module when power of the signal received at the antenna is at or above a second threshold value.

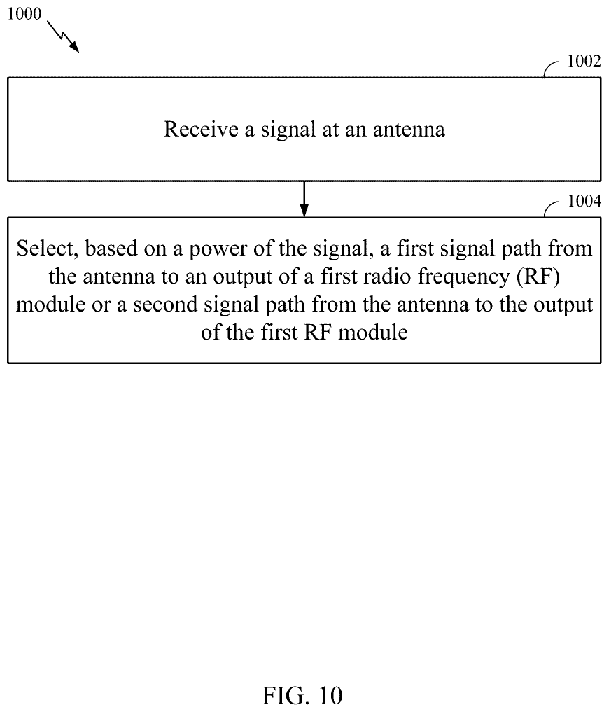

FIG. 10 is a flow diagram of example operations 1000 for an RF front-end circuit (e.g., the RF front-end circuit 300, 500, 600, 700, and 800 of FIGS. 5A, 5B, 5C, 6A, 6B, 6C, 6D, 6E, 7A, 7B, 7C, 7D, 8A, 8B, 8C, and 8D, respectively), in accordance with certain aspects of the present disclosure.

The operations 1000 may include, at block 1002, receiving a signal at an antenna (e.g., antenna 302).

At block 1004, the operations may include selecting, based on a power of the signal, a first signal path from the antenna to an output of a first RF module (e.g., first RF module 320) or a second signal path from the antenna to the output of the first RF module. In certain aspects, the selecting at block 1004 may include selecting the first signal path when the power of the signal received at the antenna is at or below a first threshold value (e.g., the power is lower). In certain aspects, the selecting at block 1004 may include selecting the second signal path when the power of the signal received at the antenna is at or above a second threshold value (e.g., the power is higher). Selecting the first signal path may include using at least a first component (e.g., LNA 322) to amplify the received signal. Selecting the second signal path may include using at least a second component (e.g., attenuating element A1, attenuating element A2, attenuating element A3, and switching circuit 310) to attenuate the received signal.

In certain aspects, the first RF module may include an integrated circuit, such as, for example a front-end integrated circuit. The first RF module may include a BT RF module or a WLAN RF module.

While not shown, additional processing steps/paths could also be implemented. For example, as described in the example configurations of FIGS. 5-8, RF signals at different power levels may be routed to a same RF module, but through elements with different levels of attenuation.

### Example Aspects

In addition to the various aspects described above, specific combinations of aspects are within the scope of the present disclosure, some of which are detailed below:

Aspect 1: A radio frequency (RF) front-end circuit comprising: a first RF module; a second RF module; and a switching circuit for selecting a first signal path from an antenna to an output of the first RF module when power of a signal received at the antenna is at or below a first threshold value, or a second signal path from the antenna to the output of the first RF module when power of the signal received at the antenna is at or above a second threshold value.

Aspect 2: The RF front-end circuit of Aspect 1, wherein at least one of the first RF module or the second RF module comprises an integrated circuit.

Aspect 3: The RF front-end circuit of Aspect 1 or 2, wherein at least one of the first RF module or the second RF module comprises a front-end integrated circuit.

Aspect 4: The RF front-end circuit according to any of Aspects 1-3, wherein: the first RF module comprises a Bluetooth (BT) RF module; and the second RF module comprises a wireless local area network (WLAN) RF module.

Aspect 5: The RF front-end circuit according to any of Aspects 1-4, wherein the first signal path comprises at least a first component to amplify the received signal.

Aspect 6: The RF front-end circuit of Aspect 5, wherein the second signal path comprises at least a second component to attenuate the received signal.

Aspect 7: The RF front-end circuit of Aspect 6, wherein the first component comprises a low noise amplifier (LNA) of the second RF module.

Aspect 8: The RF front-end circuit of Aspect 7, wherein the second component comprises an attenuating element or a directional coupler.

Aspect 9: The RF front-end circuit of Aspect 8, wherein the switching circuit comprises a first switch in the first RF module.

Aspect 10: The RF front-end circuit of Aspect 9, wherein the switching circuit further comprises a second switch coupled between the antenna and the first RF module.

Aspect 11: The RF front-end circuit of Aspect 6 or 8, wherein: the first component comprises a low noise amplifier (LNA) coupled between the antenna and the second RF module; and the switching circuit comprises at least a first switch to route the received signal through the LNA when the power of a signal received at the antenna is at or below the first threshold value.

Aspect 12: A method for routing signals, the method comprising: receiving a signal at an antenna; and selecting, based on a power of the signal, a first signal path from the antenna to an output of a first radio frequency (RF) module or a second signal path from the antenna to the output of the first RF module.

Aspect 13: The method of Aspect 12, wherein the selecting comprises selecting the first signal path when the power of the signal received at the antenna is at or below a first threshold value.

Aspect 14: The method of Aspect 12 or 13, wherein the selecting comprises selecting the second signal path when the power of the signal received at the antenna is at or above a second threshold value.

Aspect 15: The method according to any of Aspects 12-14, wherein the first RF module comprises an integrated circuit.

Aspect 16: The method according to any of Aspects 12-14, wherein the first RF module comprises a front-end integrated circuit.

Aspect 17: The method according to any of Aspects 12-16, wherein: the first RF module comprises a Bluetooth (BT) RF module or a wireless local area network (WLAN) RF module.

Aspect 18: The method according to any of Aspects 12-17, wherein selecting the first signal path comprises using at least a first component to amplify the received signal.

Aspect 19: The method of Aspect 18, wherein selecting the second signal path comprises using at least a second component to attenuate the received signal.

Aspect 20: A system for routing signals comprising: a first signal path from an antenna to an output of a first RF module; a second signal path from the antenna to the output of the first RF module; a switching circuit; memory having computer-executable instructions stored thereon; and one or more processors coupled to the memory, the one or more processors, individually or collectively, being configured to: select, using the switching circuit, the first signal path when power of a signal received at the antenna is at or below a first threshold value, or select, using the switching circuit, the second signal path when power of the signal received at the antenna is at or above a second threshold value.

### ADDITIONAL CONSIDERATIONS

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A radio frequency (RF) front-end circuit comprising:
a first RF module;
a second RF module; and
a switching circuit for selecting
a first signal path from an antenna to an output of the first RF module when power of a signal received at the antenna is at or below a first threshold value, or
a second signal path from the antenna to the output of the first RF module when power of the signal received at the antenna is at or above a second threshold value.

2. The RF front-end circuit of claim 1, wherein at least one of the first RF module or the second RF module comprises an integrated circuit.

3. The RF front-end circuit of claim 1, wherein at least one of the first RF module or the second RF module comprises a front-end integrated circuit.

4. The RF front-end circuit of claim 1, wherein:
the first RF module comprises a Bluetooth (BT) RF module; and
the second RF module comprises a wireless local area network (WLAN) RF module.

5. The RF front-end circuit of claim 1, wherein the first signal path comprises at least a first component to amplify the received signal.

6. The RF front-end circuit of claim 5, wherein the second signal path comprises at least a second component to attenuate the received signal.

7. The RF front-end circuit of claim 6, wherein the first component comprises a low noise amplifier (LNA) of the second RF module.

8. The RF front-end circuit of claim 7, wherein the second component comprises an attenuating element or a directional coupler.

9. The RF front-end circuit of claim 8, wherein the switching circuit comprises a first switch in the first RF module.

10. The RF front-end circuit of claim 9, wherein the switching circuit further comprises a second switch coupled between the antenna and the first RF module.

11. The RF front-end circuit of claim 6, wherein:
the first component comprises a low noise amplifier (LNA) coupled between the antenna and the second RF module; and
the switching circuit comprises at least a first switch to route the received signal through the LNA when the power of a signal received at the antenna is at or below the first threshold value.

12. A method for routing signals, the method comprising:
receiving a signal at an antenna; and
selecting, based on a power of the signal, a first signal path from the antenna to an output of a first radio frequency (RF) module or a second signal path from the antenna to the output of the first RF module.

13. The method of claim 12, wherein the selecting comprises selecting the first signal path when the power of the signal received at the antenna is at or below a first threshold value.

14. The method of claim 12, wherein the selecting comprises selecting the second signal path when the power of the signal received at the antenna is at or above a second threshold value.

15. The method of claim 12, wherein the first RF module comprises an integrated circuit.

16. The method of claim 12, wherein the first RF module comprises a front-end integrated circuit.

17. The method of claim 12, wherein:
the first RF module comprises a Bluetooth (BT) RF module or a wireless local area network (WLAN) RF module.

18. The method of claim 12, wherein selecting the first signal path comprises using at least a first component to amplify the received signal.

19. The method of claim 18, wherein selecting the second signal path comprises using at least a second component to attenuate the received signal.

20. A system for routing signals comprising:
a first signal path from an antenna to an output of a first RF module;
a second signal path from the antenna to the output of the first RF module;
a switching circuit;
memory having computer-executable instructions stored thereon; and
one or more processors coupled to the memory, the one or more processors, individually or collectively, being configured to:
select, using the switching circuit, the first signal path when power of a signal received at the antenna is at or below a first threshold value, or
select, using the switching circuit, the second signal path when power of the signal received at the antenna is at or above a second threshold value.
